(19) United States
(12) Patent Application Publication
(10) Pub. No.: US 2012/0017829 A1
(43) Pub. Date: Jan. 26, 2012

(54) REDUCTION OF STRAY LIGHT DURING SINTERINIG

(75) Inventors: C. Richard PANICO, Medford, MA (US); Roger WILLIAMS, Acton, MA (US); Ryan HATHAWAY, Lynn, MA (US)

(73) Assignee: XENON CORPORATION, Wilmington, MA (US)

(21) Appl. No.: 13/188,172

(22) Filed: Jul. 21, 2011

Related U.S. Application Data
(60) Provisional application No. 61/366,225, filed on Jul. 21, 2010.

(51) Int. Cl. C23C 14/28

(52) U.S. Cl. 118/620; 427/597

(57) ABSTRACT

A conductive particle sintering system has light blocking coating, aperture, or shutter to allow energy from a radiant source, such as a flash lamp, to reach a desired portion of a workpiece to be sintered, while blocking stray light from reaching other workpieces and/or other portions of a workpiece being processed to prevent stray light from partially sintering the other workpieces and/or other portions of a workpiece.

### CROSS-REFERENCE TO RELATED APPLICATION

This application claims priority from Provisional Application Ser. No. 61/366,225, filed Jul. 21, 2010, which is incorporated herein by reference.

### BACKGROUND

This disclosure relates to systems and methods for sintering, and particularly, metal particles.

In processing a material with fine particles, sintering is a process whereby metal particles are heated and made to cohere to one another, forming a continuous metallic film. Sintering systems and methods can require high temperatures. In the case of sintering a metal on a substrate, high temperature can damage the substrate. Nanotechnology has made possible the sintering of metallic inks, formed on substrates, at lower temperatures than with larger particles. While a metal has a specific melting temperature, a nanometal, which is a nanometer-sized particle of a metal, can melt at a lower temperature. A sintering system using pulsed light and/or high intensity continuous light can bind nanometals to one another and onto substrates using lower temperatures than those used with conventional sintering systems.

Sintering has broad applications, such as in the emerging field of printed electronics. Printed electronics includes printing electrically functional devices, including, but not limited to, lighting devices, batteries, super capacitors, and solar cells. Printing electronic devices can be less costly and more efficient than conventional methods for producing such devices.

### BRIEF DESCRIPTION OF THE DRAWINGS

The features and advantages of certain embodiments are illustrated in the accompanying drawings.

FIG. 1 is a schematic illustration of a system and method showing the striping issue.

FIG. 2 is a graphical representation of the effect of different energy levels on a conductive ink.

FIG. 3 is a schematic illustration of a system and method to reduce stray light during sintering using a mask.

### DETAILED DESCRIPTION

Conductive inks, such as those including nanometals, can be sintered with radiant energy that can include combinations of pulsed light, high intensity continuous light, ultraviolet light, radiation, and thermal energy. A UV flash lamp, for example, can be used. It provides UV radiation and thermal energy (and also includes energy in the visible range and infrared range). When the particles are sintered, they form a continuous conductive path that has a conductivity that is much higher than the particles have pre-sintering.

When operating on a sheet or a moving web, there is a potential issue with a phenomenon referred to here as “striping.” Striping occurs when the substrate moving towards the main energy of the radiant source, such as a pulsed lamp, has already been exposed to stray light before it reaches the point where it is to be sintered. The stray light can cause the conductive ink to be only partially sintered and converted to a bulk state. In the bulk state, the conductive ink is no longer a nanoparticle and thus melts at a higher temperature, but the material might not be sufficiently sintered to have the desired conductivity. Therefore, the pulsed light and/or high intensity continuous light at lower temperatures might not properly sinter the metal when the desired portion of the workpiece reaches the location for sintering. This issue can also arise if workpieces are near each other, e.g., on a conveyor, and a workpiece is exposed to stray light/energy before it is in an appropriate position for sintering.

The striping phenomenon can occur with various nanometals, including but not limited to copper, silver, gold, palladium, tin, tungsten, titanium, chromium, vanadium, aluminum, and alloys thereof. In some embodiments, the disclosed systems and methods prevent partial sintering of copper nanometals. At radiant energy levels lower than a first threshold range, there will be no sintering. Above that first threshold and below a second threshold, copper nanoparticles only partially sinter, but do not reach the desired level of conductivity. The conductivity of this material is higher than that of the un-sintered nanoparticles, but will not be as high as the material that receives radiant energy levels that are at a preferred range above the second threshold range. When the partially sintered material is exposed to radiant energy levels for a second time with an intensity that should be sufficient to convert the non-sintered nanoparticle to a fully conductive state, the conductivity of the previously partially sintered nanoparticles does not improve.

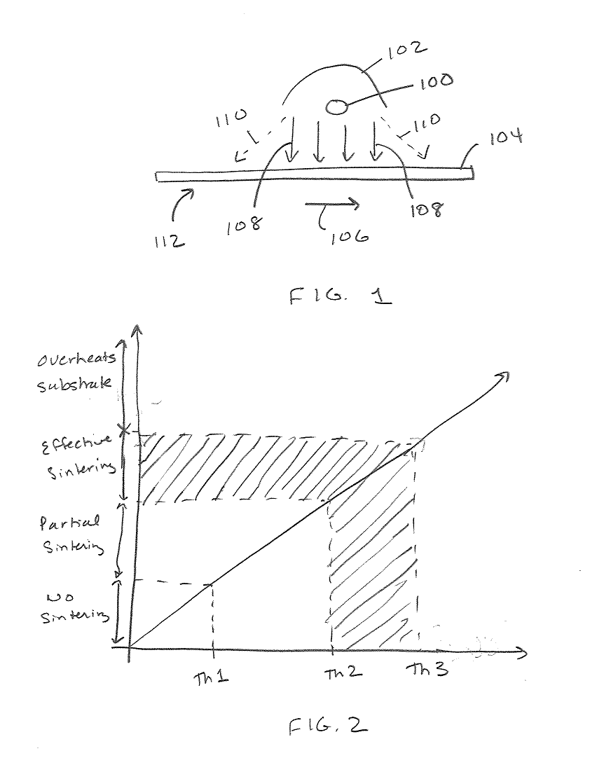

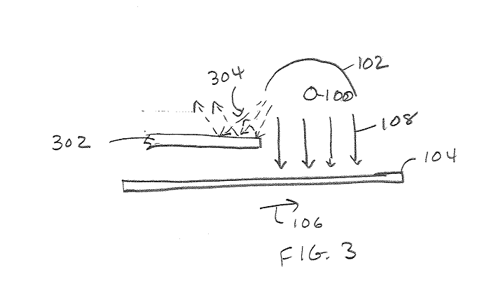

This phenomenon is demonstrated in FIGS. 1 and 2. FIG. 1 is a representation of a lamp system, such as a flash lamp system with a lamp 100, reflector 102, and workpiece 104 moving on a conveyor in a direction 106. Workpiece 104 can include a substrate with traces on top (not shown) of a conductive ink with nanoparticles, such as copper nanoparticles. The energy represented by arrows 108 is sufficient to sinter the conductive ink to obtain a desired conductivity level. The energy from dashed arrows 110 is sufficient to partially sinter the conductive ink, but with the result that the traces do not have the desired conductively. Because the direction of travel 106 is to the right, this is typically just a potential problem with the left-hand side 112. By the time the part on the left reaches the portion exposed to energy represented by arrows 108, it could be partially sintered, and the energy is thus ineffective to complete the sintering process.

FIG. 2 graphically represents the issue in a general way. With energy below a first threshold Th1, there is no sintering. With energy above a third threshold Th3, the substrate can be damaged, at least for some substrates such as paper, polyester, and others. With energy above a second threshold Th2 and below threshold Th3, the energy is effective to increase the conductivity of the trace to a desired level. With energy between thresholds Th1 and Th2, there is only partial sintering that, at least in some materials, can help prevent full effective sintering even if the conductive ink is exposed to energy greater than Th2. This, it is desirable to be in the region bounded by Th2 and Th3, as shown shaded in FIG. 2. The thresholds can be dependent on various factors in the system and in the workpiece(s), such as the type of material to be sintered, its geometry, and the nature of the substrate.

The present disclosure relates to systems and methods for reducing stray light during sintering, such that undesired partial sintering is reduced or eliminated. Embodiments in this disclosure relate to systems and methods for blocking energy to a sufficient degree so as to avoid partial sintering of nanoparticles in workpieces or regions of workpieces before they are at a desired location to receive energy for sintering. In one or more embodiments, the disclosed light blockers prevent an “intermediate phase” wherein nanoparticles are only partially sintered after a first exposure to light energy but do not have improved conductivity after a second exposure to light energy.

Blocking energy can have some disadvantage in that not all of the energy from the radiant energy source is utilized. However, it has been found that using the light blocker of the instant disclosure results in fully sintered nanoparticles with sufficient conductivity. The disclosed systems and methods avoid the problem of “striping” and partial sintering.

During the sintering process, an electronic material, such as a conductor, is added onto a substrate. The material to be sintered can be added onto the substrate using one or more technologies well known in the art, including screen-printing, inkjet printing, gravure, laser printing, inkjet printing, xerography, pad printing, painting, dip-pen, syringe, airbrush, flexography, evaporation, sputtering, etc. Various substrates can be used with the disclosed systems and methods. Substrates include but are not limited to low-temperature, low-cost substrates such as paper and polymer substrates such as poly(diallyldimethylammonium chloride (PDAA), polyacrylic acid (PAA), poly (allylamine hydrochloride) (PAH), poly(4-styrenesulfonic acid), poly(vinyl sulfate) potassium salt, 4-styrenesulfonic acid sodium salt hydrate, polystyrene sulfonate (PSS), polyethylene imine (PEI), polyethylene terephthalate (PET), polyethylene, etc.

Referring to FIG. 3, in one aspect, systems and methods to reduce stray light during sintering include using one or more light blockers. In one or more embodiments, the light blocker is a flat mask. FIG. 3 has components that are the same as FIG. 1, but further adds a mask 302 for blocking energy represented by arrows 304. Mask 302 is positioned between the light source and a portion of the substrate to reduce or eliminate partial sintering by blocking stray light from irradiating the advancing substrate but allowing direct light exposure, such as directly under the light source as represented by arrows 108, such that full sintering can occur. As shown here, the mask can be on the incoming side of the conveyor, and not on the other side, or the mask can be on both sides of the conveyor direction to create an aperture. The aperture can have different shapes and sizes, including but not limited to roughly triangular, circular, oval, rectangular, etc. It is desirable for the mask to block energy that would otherwise be below threshold Th2 (FIG. 2) from reaching any workpiece or portion of the workpiece before that workpiece or portion of the workpiece is exposed to energy exceeding Th2 and thus sintering as desired.

In some embodiments, a conveyor belt system moves the substrate continuously during sintering, and thus typically coordinated in speed with the flashing frequency of the lamp; in other embodiments, the conveyor is moved in a step-wise manner. The light source could be moved, with a workpiece or number of workpieces being stationary.

In one embodiment, the sintering system comprises an energy source, a substrate, nanomaterial positioned on the substrate, and one or more light blockers, wherein the light blocker is positioned between the light source and the substrate, such that the light blocker blocks a sufficient amount of light energy to prevent partial sintering of the nanomaterial. The nanomaterial includes but is not limited to copper, silver, gold, palladium, tin, tungsten, titanium, chromium, vanadium, aluminum, and alloys thereof.

In one embodiment, the light blocker is in close contact, i.e. close proximity or distance, to the light source. In another embodiment, the light blocker is in close contact to the substrate. In one or more embodiments, the light blocker is oriented in a vertical, horizontal, or angled direction. The proximity of the light blocker depends on various parameters of the system, including physical aperture size and shape, speed of movement, the type of radiant energy source, and the nature of the material. In some embodiments, the energy source includes a pulsed or flash lamp as the main radiant energy source.

In one embodiment, the light blocker is positioned in close proximity to the substrate but does not touch the substrate material. In one embodiment, the light blocker is positioned so that it is at least 50% of the distance from the lamp to the workpiece. In other embodiments, the mask is at least 60%, or 70%, or 80%, or 90%, or 95% of the distance from the lamp to the workpiece. The exact distance can depend on one or more parameters of the system, such as the geometry of the mask, the configuration of workpiece, speed of conveyor, and energy level.

In one or more embodiments, a movable shutter coordinates the timing of the substrate's exposure to the light source. In one or more embodiments, the substrate triggers a detector that causes a light blocker, such as in the form of a light shield, to move to a certain point until the substrate is directly below the light source.

In another aspect, one or more reflectors are used as masks that can further direct energy. Reflectors include, but are not limited to, imaging reflectors. In some embodiments, a specific portion of the reflector is removed to reduce angled light. In some embodiments, the reflector reflects light emitted from the light source toward the substrate. The reflector creates an aperture and maximizes directed energy that is applied to the substrate. The reflecting surface of the reflector can be formed at a predetermined angle to direct the light from the light source toward a position to be treated on a substrate. The position of the reflector between the substrate and the light source can be adjusted so that the intensity of the reflected light from the reflecting surface can be increased or decreased.

In one embodiment, the light source emits light in an upward direction. In another embodiment, the light source emits light in a downward direction. The direction in which the light source emits light can be determined based on the conditions and positions of the various workpieces, including the substrate and the light blocker.

The systems and methods described herein can be used alone or in conjunction with one another to reduce stray light during sintering.

The sintering systems can include a conveyor system with the substrate located directly above the conveyor. The conveyor can operate, for example, at speeds from 2 feet/min to 1000 feet/min to move the substrate. A conveyor control module can determine the speed at which the substrate is being moved. For example, the conveyor system can operate in a start/stop motion as well as in a continuous motion. The motion of the conveyor is coordinated with the flashing action to ensure that the workpiece gets a sufficient amount of energy for sintering where needed. The workpiece can include larger pieces, such that the energy can be provided to a portion at one time, and then is provided to another portion. Or, there can be a succession of different pieces, e.g., on a conveyor. The mask can allow the workpieces to be placed closer together so that the sintering to one (or a group), does not partially sinter others.

The system can include a contact shield is attached to the side of the mask that first comes into contact with the lamp. The system can include a collimating device for narrowing a beam of light and/or aligning the beam of light in a specific direction.

In another aspect, after the electronic material is added onto the substrate, but before the substrate with the electronic material reaches a light sintering station, the substrate is coated with a solution that reduces or eliminates partial sintering from stray light, but allows sintering from directed light (e.g., the light under the lamp), this serving as a light blocker for energy coming in at an angle. In one or more embodiments, the coating can be later removed during sintering by the force of the directed light and/or “washed away” with a follow-on process.

Exemplary ranges of pulsed lamp operating parameters include the following:
1. Pulse Duration: 1 [symbol] s to 100,000 [symbol] s measured at ⅓ peak value.
2. Energy per Pulse: 1 joule to 5,000 joules.
3. Pulse Rates: Single pulse to 1,000 pulses per second.
4. Pulse mode: single pulse, burst, or continuous pulsing.
5. Lamp Configuration (shape): linear, spiral, or u-shape.
6. Spectral Output: 180 nanometers to 1,000 nanometers.
7. Lamp Cooling: ambient, forced air, or water.
8. Wavelength Selection (external to the lamp): none or IR filter.
9. Uniformity Ranges ±0.1% to ±25% Center to Edge
10. Lamp Housing Window: none, pyrex, quartz, suprasil, or sapphire.
11. Top and Bottom Sequencing: Any combination in between from 0% to 100% top lamp to 0% to 100% bottom lamp.

Having described embodiments of the present inventions, it should be apparent that modifications can be made without departing from the scope of the inventions described herein. The system can be used in conjunction with other filters.

What is claimed is:

1. A sintering system, comprising
a flash lamp system including a lamp for providing energy to a workpiece and having a pulse duration of 1 [symbol] s to 100,000 [symbol] s measured at ⅓ peak value, and 1-5000 Joules per pulse, and a light blocker positioned between the lamp and the workpiece to block energy from the lamp from reaching a first portion of the workpiece, while allowing energy from the lamp to reach a second portion of the workpiece.

2. The system of claim 1, in combination with the workpiece, wherein the workpiece includes a substrate with a conductive ink having metallic nanomaterial on the substrate.

3. The system of claim 2, wherein the light blocker blocks a sufficient amount of energy to prevent partial sintering of the nanomaterial.

4. The system of claim 3, wherein the nanomaterial includes copper nanoparticles.

5. The system of claim 1, wherein the lamp system further includes a conveyor for holding workpieces, the conveyor being movable in a direction of travel that is substantially perpendicular to the direction energy is applied to workpieces from the lamp, the mask blocking energy from a portion of the workpiece on the incoming side of the conveyor.

6. The system of claim 1, wherein the flash lamp includes a UV lamp.

7. The system of claim 1, wherein the lamp includes a flash lamp, and wherein the light blocker includes a mask with an aperture.

8. The system of claim 1, wherein light blocker includes a mask that prevents energy below a threshold value from reaching the first portion of the workpiece, while allowing energy above a threshold value from reaching the second portion of the workpiece.

9. The system of claim 2, wherein the workpiece is sufficiently large that the lamp sinters a portion at one time.

10. The system of claim 2, wherein the workpiece includes discrete units arranged so that one or more is exposed to energy from the lamp while one or more other pieces are positioned such that the energy is blocked from such one or more other pieces.

11. The system of claim 1, wherein the light blocker includes a shutter.

12. A flash lamp sintering system, comprising a flash lamp system including a flash lamp for providing to a workpiece having a substrate and a conductive ink with metallic particles, the energy being greater than a second threshold sufficient to sinter the conductive ink to have a desired conductivity and less than a third threshold above which the energy damages the substrate, and a light blocker positioned between the lamp and the workpiece to block energy greater than a first threshold, wherein the first threshold is less than a second threshold, from the lamp from reaching a first portion of the workpiece such that the energy would otherwise partially sinter the workpiece, while allowing energy from the lamp between the second and third thresholds from reach a desired second portion of the workpiece to sinter the conductive ink in the workpiece.

13. The system of claim 12, wherein the energy to the second portion is sufficient to sinter a conductive ink having nanoparticles.

14. The system of claim 12, wherein the energy to the second portion is sufficient to sinter a conductive ink having copper nanoparticles.

15. The system of claim 12, wherein the system includes a conveyor for holding workpieces, the conveyor being movable in a direction of travel that is substantially perpendicular to the direction energy is applied to workpieces from the lamp, the light blocker blocking energy from a portion of the workpiece on the incoming side of the conveyor.

16. The system of claim 12, wherein the flash lamp provides pulses of energy with a pulse duration of 1 [symbol] s to 100,000 [symbol] s measured at ⅓ peak value, and 1-5000 Joules per pulse.

17. A method for sintering workpieces that have conductive ink with fine particles, comprising moving a workpiece along a conveyor to a region where a desired portion of the workpiece is exposed to energy, applying sufficient energy with a flash lamp to a desired region to allow the conductive ink to be sintered, and blocking energy from other portions of the workpiece to prevent partial sintering.

18. The method of claim 17, comprising providing introducing a workpiece along a conveyor for holding workpieces, the conveyor being movable in a direction of travel that is substantially perpendicular to the direction energy is applied to workpieces from the lamp, wherein the blocking includes blocking energy from a portion of the workpiece on the incoming side of the conveyor.

19. The method of claim 17, wherein the sintering includes sintering a substrate with a conductive ink having metallic particles.
